(19) United States
(12) Patent Application Publication
(10) Pub. No.: US 2013/0334516 A1
(43) Pub. Date: Dec. 19, 2013

(54) OPTOELECTRONIC COMPONENT HAVING DOPED LAYERS

(71) Applicants: Andre Weiss, Ulm (DE); Bert Männing, Dresden (DE); Gunter Mattersteig, Ulm (DE)

(72) Inventors: Andre Weiss, Ulm (DE); Bert Männing, Dresden (DE); Gunter Mattersteig, Ulm (DE)

(73) Assignee: heliatek GmbH, Dresden (DE)

(21) Appl. No.: 13/976,386

(22) PCT Filed: Dec. 22, 2011
(86) PCT No.: PCT/EP2011/073852

§ 371 Date: Sep. 4, 2013

(30) Foreign Application Priority Data
Dec. 27, 2010 (DE) 102010056519.9

(51) Int. Cl. H01L 51/00

(52) U.S. Cl. CPC H01L 51/0077
USPC 257/40; 438/99

(57) ABSTRACT

The invention relates to an organic electronic or optoelectronic component, comprising an electrode and a counter-electrode and a layer system between the electrode and the counter-electrode, wherein the layer system contains at least one organic layer and at least one doped layer, wherein the dopant in the doped layer represents a stronger Lewis acid than antimony pentafluoride (SbF5) or a stronger Lewis base than 1,8-bis(dimethylamino)napthalene based on the calculation of fluoride ion affinity.

The invention relates to novel dopants for organic systems and layer systems, to the use thereof for doping an organic semiconductive matrix material, as a charge injection layer, as a hole blocker layer, as an electrode material, as the transport material itself, as a storage material in electronic or optoelectronic components, and to the use of matrix materials doped therewith in organic electronic or optoelectronic components, and also to organic optoelectronic components comprising these dopants.

It is known that the electrical properties of organic semiconductors, especially the electrical conductivity thereof, can be altered by doping, as is also the case for inorganic semiconductors such as silicon semiconductors. In this context, by generation of charge carriers in the matrix material, an increase in the conductivity, which is quite low at first, and, depending on the type of dopant used, a change in the Fermi level of the semiconductor is achieved. Doping here leads to an increase in the conductivity of charge carrier transport layers, which reduces ohmic losses, and to an improved transition of the charge carriers between contacts and organic layer. Inorganic dopants such as alkali metals (e.g. cesium) or Lewis acids (e.g. FeCl₃; SbCl₅) are usually disadvantageous in the case of organic matrix materials due to the high diffusion coefficients thereof, since the function and stability of the electronic components is impaired (see D. Oeter, Ch. Ziegler, W. Göpel Synthetic Metals (1993) 61 147; Y. Yamamoto et al. (1965) 2015, J. Kido et al. Jpn J. Appl. Phys. 41 (2002) L358). Moreover, the latter dopants have such a high vapor pressure that industrial use is very questionable. Moreover, the reduction potentials of these compounds are often too low to dope hole conductor materials of real industrial interest. In addition, the extremely aggressive reaction characteristics of these dopants complicate industrial use.

The use of doped organic layers or layer systems in organic components, specifically organic solar cells and organic light-emitting diodes, is known (e.g. WO2004083958). Various materials or material classes have been proposed as dopants, as described in DE102007018456, WO2005086251, WO2006081780, WO2007115540, WOP2008058525, WO2009000237 and DE102008051737.

It is also known that dopants can be released via chemical reactions in the semiconductive matrix material, in order to provide dopants. The reduction potential of the dopants released in this way, however, is often insufficient for various applications, for instance for organic light-emitting diodes (OLEDs). Moreover, in the case of release of the dopants, further compounds and/or atoms, for example atomic hydrogen, are produced, which impairs the properties of the doped layer or of the corresponding electronic components.

The problem addressed by the present invention is that of providing novel dopants for use in electronic and optoelectronic components, which overcome the disadvantages from the prior art.

More particularly, the novel dopants are to have sufficiently high redox potentials without being disruptive influences on the matrix material and are to provide an effective increase in the number of charge carriers in the matrix material and be comparatively easy to handle.

According to the invention, the problem is solved by compounds which by the measure of fluoride ion affinity (FIA) are a stronger Lewis acid than antimony pentafluoride (SbF₅) or a stronger Lewis base than 1,8-bis(dimethylamino)naphthalene, and can be used as dopants in organic electronic and optoelectronic components.

The measure of fluoride ion affinity (FIA) is based on the scale of fluoride ion affinity in the gas phase (FIA). The strength of the binding of a fluoride ion does not depend on further factors, for example on hydrogen bonds in the case of the traditional acid-base protagonists, water or hydroxide.

The fluoride ion affinity FIA links the strength of a Lewis acid to the energy which is released in the binding of a fluoride ion F⁻.

By definition, the FIA corresponds to the value of the bonding enthalpy ΔH with the reverse sign. The strength of a Lewis acid can thus be read off directly from its entry on the FIA scale.

To determine reliable FIA values, it is possible to use quantum-chemical calculations on isodesmic reactions, in which the type and number of bonds is maintained.

Dopants mean compounds which occur with a proportion by mass of at most 35%, but preferably at most 30%, in a layer, preferably a charge carrier transport layer, of the layer system of an organic electronic or optoelectronic component. The inventive compounds can also be used in the form of usually thin individual layers, but preference is given to the use thereof as dopants in a matrix material.

The inventive compounds may be organic, organometallic or inorganic compounds, but preference is given to organic or organometallic compounds.

The inventive Lewis acids are strongly electrophilic and are therefore used as p-dopants in electronic or optoelectronic components.

The inventive Lewis acids are strongly nucleophilic and are therefore used as n-dopants in electronic or optoelectronic components.

The inventive strong Lewis acids are also known as superacids in the specialist field. These are capable, among other things, of protonating the exceptionally unreactive noble gases. Use as dopants has long been ruled out owing to the high reactivity thereof, since it is crucial for industrial usability that they do not react with the matrix material but p- or n-dope it.

It has been found that, surprisingly, use of inventive compounds as dopants in organic electronic and optoelectronic components is possible in spite of the high reactivity. Preferably, both the inventive Lewis acids and the inventive Lewis bases have branched side chains or other bulky groups which sterically shield the reactive site.

In an inventive component, both the charge transport layers and the active layers can be doped, but it is usual to dope the charge carrier transport layers. In addition, various individual or mixed layers may be present. For reasons of long-term stability, it may be advantageous to form the transport system from a layer system having doped and undoped layers. In addition, thin layers are known as exciton blocker layers, for which the use of the inventive compounds as an undoped individual layer could be conceivable.

Organic electronic and optoelectronic components are understood to mean components having at least one organic layer in the layer system. An organic electronic and optoelectronic component may, inter alia, be an OLED, an organic solar cell, a field transistor (OFET) or a photodetector, particular preference being given to use in organic solar cells.

In one embodiment, the inventive compounds contain at least 10, preferably 20, but more preferably more than 30 and not more than 100 atoms. As a result, the inventive compounds are large and heavy enough to have only a low diffusion coefficient in the matrix, which is important for good function and high stability and lifetime of the electronic components, and small enough to be usable industrially via vaporization.

An illustrative but nonlimiting example of a superacid here is the compound tris(perfluoro-tert-butoxy)aluminum(III) (Al(OC(CF₃)₃)₃) (compound 1).

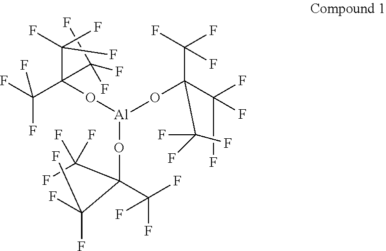

As in the case of (Al(OC(CF₃)₃)₃), the inventive Lewis acids and Lewis bases preferably have branched side chains or other bulky groups which sterically screen the central site (here, metal atom). Any possible reaction of the dopant with the matrix is made much more difficult thereby. Compound 1 consists of 43 atoms. Thus, it is large and heavy enough to have only a low diffusion coefficient in the matrix, which is important for good function and high stability and lifetime of the electronic components. Moreover, industrial use is possible, since the synthesis of tris(perfluoro-tert-butoxy)aluminum(III) (Al(OC(CF₃)₃)₃) is also known on the multigram scale.

Further examples of superacids as dopants are carborane acids H(CB₁₁H₁₂₋ₙXₙ), especially H(CB₁₁H₆X₆) and H(CHB₁₁X₁₁), where n is an integer from 0 to 12 and X is selected from the group consisting of Cl, Br, I, F, CF₃ and combinations thereof. Carborane acids are known from the literature and can be prepared, for example, from the corresponding silyl compound [R₃Si (carborane)] and HCl (Reed et al., Chem. Commun., 2005, 1669-1677). In one embodiment of the invention, the dopants used are H(CHB₁₁Cl₁₁) and H(CB₁₁H₆X₆), which can be successfully sublimed under vacuum and protonate fullerenes (e.g. C₆₀) and stabilize fullerene cations (HC₆₀⁺ and Co₆₀.⁺) due to the robust and chemically quite inert carborane skeleton (Reed et al. Science, 2000, 289, 101-103). In a further embodiment, the corresponding [R][carborane] and [R₃₋ₐHₐSi][carborane] compounds where a is an integer from 0 to 2, especially [R₃C][carborane] and [R₃Si][carborane] compounds, where [carborane] is [CB₁₁R₁₂₋ₙXₙ]⁻, n is an integer from 0 to 12, R is an alkyl, aryl and heteroaryl group, especially [CHB₁₁R′₅X₆]⁻, where R′ is selected from H or CH₃ and X is a halogen, are also used as dopants. Synthesis and properties of [R₃C][carborane] compounds (Reed et al. Angew. Chem. Int. Ed., 2004, 43, 2908-2911) and [R₃Si][carborane] compounds (Reed et al. Science, 2002, 297, 825-827) are documented in detail in the literature. The carborane acids differ from conventional superacids in that they slightly protonate weakly basic solvents and weakly basic molecules and thus generate superacidity without addition of a strong Lewis acid (e.g. SbF₅) (Reed et al. Angew. Chem. Int. Ed., 2004, 43, 5352-5355). They surpass the acid strength of trifluoromethanesulfonic acid, and exhibit even lower anion nucleophilicity and better crystallization characteristics of the salts thereof. Icosahedral carborane anions of the CHB₁₁R₅X₆⁻ type (R=H, CH₃, Cl, X=Cl, Br, I) are some of the most weakly nucleophilic, most redox-inactive and most inert anions in modern chemistry. Thus, they cannot initiate any decomposition reactions of the compounds protonated by the carborane acid thereof. FIG. 3 shows examples of anions (conjugated bases) of the claimed carborane acids (reproduced from Chem. Commun. 2005, 1669-1677).

The bulky, sterically demanding anions achieve a low diffusion coefficient in the matrix, and this, in conjunction with the low nucleophilicity and the very weak redox behavior, is of crucial importance for good function and high stability and lifetime of the electronic components. Using carborane acids as p-dopants, very stable protonated compounds are thus obtained, and these are barely decomposed, or are decomposed to a very small degree, by the carborane anion in a further reaction. The low vapor pressure of the carborane acids allows optimal doping. The positive charge carriers produced thereby have high electrophilicity and pull an electron away from the adjacent hole conductor molecules.

In one embodiment of the invention, metal compounds from the class of the pentafluorophenylamides of the general formula I

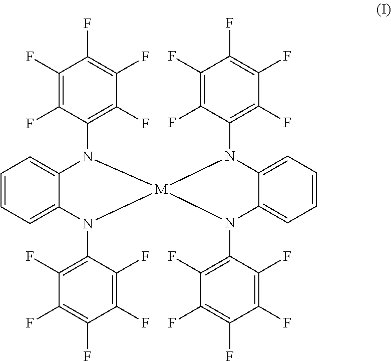

are used, where M is a metal. M is preferably selected from the group consisting of Co, Ni, Pd and Cu.

Compounds of the formula (I) have bulky groups which sterically shield the central site. Moreover, the compound of the formula (I), because of its size and mass, is suitable for use as a dopant in organic layer systems.

In a further embodiment, compounds of the general formula II

[R₃Si—X—SiR₃]⁺[BAr₄]⁻ (II)

are used, where R is independently selected from C₁-C₁₀-alkyl, C₃-C₁₀-aryl or heteroaryl and/or two adjacent R radicals together form a saturated or unsaturated ring, X is a halogen and Ar is a halogenated, preferably fluorinated, aryl or heteroaryl.

In a further embodiment, compounds of the general formula III

((R₂N)₂C═N)ₙAr (III)

are used, where R is independently C₁-C₅-alkyl, in each case substituted or unsubstituted, where two adjacent R may be joined to one another, and Ar is an aryl or heteroaryl, but preferably phenyl, naphthyl or anthryl, and n is an integer, preferably 2, 3 or 4.

In a further embodiment of the invention, compounds of the general formula IV or V

((RₘX)—NC)ₙY (IV)

((RₘX)—NC)ₙY⁻M⁺ (V)

are used, where R is in each case substituted or unsubstituted C₁ to C₁₀-alkyl, halogenated C₁ to C₁₀-alkyl, halogenyl, C₃ to C₁₄-aryl or heteroaryl having 3 to 14 aromatic atoms, X is selected from C, B, Si; Y is selected from C, B, Al; M is any cation, and n and m are each an integer, such that the molecule is outwardly uncharged.

In an advantageous embodiment of the invention, the photoactive layers of the component absorb a maximum amount of light. For this purpose, the spectral range within which the component absorbs light is as broad as possible.

In an advantageous configuration of the above embodiment of the invention, the i layer system of the photoactive component consists of a double layer or mixed layers of 2 materials or of a double mixed layer or a mixed layer with an adjacent individual layer composed of at least 3 materials.

In a further embodiment of the invention, to improve the charge carrier transport properties of the double mixed layer, the mixing ratios in the different mixed layers may the same or else different, the composition being the same or different.

In a further embodiment of the invention, a gradient of the mixing ratio may be present in the individual mixed layers, the gradient being formed in the direction of the cathode or anode.

In one configuration of the invention, the organic electronic or optoelectronic component takes the form of a tandem cell or multiple cell, for instance that of a tandem solar cell or tandem multiple cell.

In a further embodiment of the invention, the organic electronic or optoelectronic component, especially an organic solar cell, consists of an electrode and a counterelectrode and, between the electrodes, at least one photoactive layer and at least one doped layer between the photoactive layer and an electrode, which preferably serves as a charge carrier transport layer.

In a further embodiment of the invention, one or more of the further organic layers are doped wide-gap layers, the maximum absorption being <450 nm.

In a further embodiment of the invention, the HOMO and LUMO levels of the main materials are matched such that the system enables a maximum open-circuit voltage, a maximum short-circuit current and a maximum fill factor.

In a further embodiment of the invention, the organic materials used for photoactive layers are small molecules.

In a further embodiment of the invention, the organic materials used for the photoactive layers are at least partly polymers.

In a further embodiment of the invention, the photoactive layer comprises, as an acceptor, a material from the group of the fullerenes or fullerene derivatives (C₆₀, C₇₀, etc.).

In a further embodiment of the invention, at least one of the photoactive mixed layers comprises, as a donor, a material from the class of the phthalocyanines, perylene derivatives, TPD derivatives, oligothiophenes, or a material as described in WO2006092134 or DE102009021881.

The inventive components can be produced in various ways. The layers in the layer system can be applied in liquid form as a solution or dispersion by printing or coating, or can be applied by vapor deposition, for example by means of CVD, PVD or OVPD.

The term “vaporization temperature” in the context of the invention is understood to mean that temperature which is required to achieve a vapor deposition rate of 0.1 nm/s at the position of the substrate for a given vaporizer geometry (reference: source with a circular opening (diameter 1 cm) at a distance of 30 cm from a substrate arranged vertically above it) and a reduced pressure in the range of 10⁻⁴ to 10⁻¹⁰ mbar. It is unimportant here whether this is a vaporization in the narrower sense (transition from the liquid phase to the gas phase) or a sublimation.

The layer formation by vapor deposition therefore preferably gives rise to those structures in which the intermolecular interactions within the layer are maximized, such that the interfaces which can enter into strong interactions are avoided at the layer surface.

There have been literature descriptions of organic solar cells formed from vacuum deposition of nonpolymeric organic molecules, called small molecules, and these, apart from a few exceptions (Drechsel, Org. Electron., 5, 175 (2004); J. Drechsel, Synthet. Metal., 127, 201-205 (2002)), are formed in such a way that the so-called base contact on which the organic layers are deposited forms the anode (if the structure comprises an exclusively hole-conducting or p-doped layer, it adjoins the base contact). The anode is generally a transparent conductive oxide (often indium tin oxide, abbreviated to ITO; it may also be ZnO:Al), but it may also be a metal layer or a layer of a conductive polymer. After deposition of the organic layer system comprising the photoactive mixed layer, a usually metallic cathode is deposited.

In a further embodiment of the invention, the component is formed as a single cell with the nip, ni, ip, pnip, pni, pip, nipn, nin, ipn, pnipn, pnin, pipn, nip, ipni, pnip, nipn or pnipn structure, where n is a negatively doped layer, i is an intrinsic layer which is undoped or slightly doped, and p is a positively doped layer.

In a further embodiment of the invention, the component is formed as a tandem cell composed of a combination of nip, ni, ip, pnip, pni, pip, nipn, nin, ipn, pnipn, pnin or pipn structures.

In a particularly preferred embodiment of the above-described structures, this takes the form of a pnipnipn tandem cell.

In a further embodiment, the acceptor material in the mixed layer is at least partly in crystalline form.

In a further embodiment, the donor material in the mixed layer is at least partly in crystalline form.

In a further embodiment, both the acceptor material and the donor material in the mixed layer are at least partly in crystalline form.

In a further embodiment, the acceptor material has an absorption maximum in the wavelength range of >450 nm.

In a further embodiment, the donor material has an absorption maximum in the wavelength range of >450 nm.

In a further embodiment, the n material system consists of one or more layers.

In a further embodiment, the p material system consists of one or more layers.

In a further embodiment, the n material system comprises one or more doped wide-gap layers.

The term “wide-gap layers” defines layers having an absorption maximum in the wavelength range of <450 nm.

In a further embodiment, the p material system comprises one or more doped wide-gap layers.

In a further embodiment, the component comprises a p-doped layer between the photoactive i layer and the electrode present on the substrate, in which case the p-doped layer has a Fermi level which is at most 0.4 eV, but preferably less than 0.3 eV, below the electron transport level of the i layer.

In a further embodiment, the component comprises an n layer system between the photoactive i layer and the counterelectrode, in which case the additional n-doped layer has a Fermi level which is at most 0.4 eV, but preferably less than 0.3 eV, above the hole transport level of the i layer.

In a further embodiment, the acceptor material is a material from the group of the fullerenes or fullerene derivatives (preferably C₆₀ or C₇₀) or a PTCDI derivative (perylene-3,4,9,10-bis(dicarboximide) derivative).

In a further embodiment, the donor material is an oligomer, especially an oligomer according to WO2006092134, a porphyrin derivative, a pentacene derivative or a perylene derivative such as DIP (diindenoperylene), DBP (dibenzoperylenes).

In a further embodiment, the p material system comprises a TPD derivative (triphenylamine dimer), a spiro compound such as spiropyrans, spirooxazines, MeO-TPD (N,N,N′,N′-tetrakis(4-methoxyphenyl)benzidine), di-NPB (N,N′-diphenyl-N,N′-bis(N,N′-di(1-naphthyl)-N,N′-diphenyl-(1,1′-biphenyl)-4,4′-diamine), MTDATA (4,4′,4″-tris-(N-3-methylphenyl-N-phenylamino)triphenylamine), TNATA (4,4′,4″-tris [N-(1-naphtyl)-N-phenylamino]triphenylamine, BPAPF (9,9-bis{4-[di-(p-biphenyl)aminophenyl]}fluorene), NPAPF (9,9-bis [4-(N,N′-bis-naphthalen-2-ylamino)phenyl]-9H-fluorene), spiro-TAD (2,2′,7,7′-tetrakis(diphenylamino)-9,9′-spirobifluorene), PV-TPD (N,N-di-4-(2,2-diphenylethen-1-yl)phenyl-N,N-di(4-methylphenyl)phenylbenzidine), 4P-TPD (4,4′-bis(N,N-diphenylamino)tetraphenyl), or a p material described in DE102004014046.

In a further embodiment, the n material system comprises fullerenes, for example C₆₀, C₇₀; NTCDA (1,4,5,8-naphthalenetetracarboxylic dianhydride), NTCDI (naphthalenetetracarboxylic diimide) or PTCDI (perylene-3,4,9,10-bis(dicarboximide)).

In a further embodiment, one electrode is transparent with a transmission of >80% and the other electrode is reflective with a reflection of >50%.

In a further embodiment, the component is semitransparent with a transmission of 10-80%.

In a further embodiment, the electrodes consist of a metal (e.g. Al, Ag, Au or a combination thereof), a conductive oxide, especially ITO, ZnO:Al or another TCO (transparent conductive oxide), a conductive polymer, especially PEDOT/PSS (poly(3,4-ethylenedioxythiophene) poly(styrenesulfonate)) or PANI (polyaniline), or a combination of these materials.

In a further embodiment of the invention, use of light traps extends the optical pathway of the incident light in the active system.

In a further embodiment, the light trap is implemented by forming the component on a periodically microstructured substrate and ensuring the homogeneous function of the component, i.e. short circuit-free contacting and homogeneous distribution of the electrical field over the whole area, by the use of a doped wide-gap layer. Ultrathin components have, on structured substrates, an increased risk of formation of local short circuits, and so such an obvious inhomogeneity ultimately endangers the functionality of the overall component. This short-circuit risk is reduced by the use of the doped transport layers.

In a further embodiment of the invention, the light trap is implemented by forming the component on a periodically microstructured substrate and ensuring the homogeneous function of the component, the short circuit-free contacting thereof and a homogeneous distribution of the electrical field over the whole area by the use of a doped wide-gap layer. It is particularly advantageous here that the light passes through the absorber layer at least twice, which can lead to increased light absorption and as a result to an improved efficiency of the solar cell.

In a further embodiment of the invention, the light trap is implemented by virtue of a doped wide-gap layer having a smooth interface to the i layer and a rough interface to the reflective contact. The rough interface can be achieved, for example, by periodic microstructuring. The rough interface is particularly advantageous when it reflects the light in a diffuse manner, which leads to an extension of the light pathway within the photoactive layer.

In a further embodiment, the light trap is implemented by forming the component on a periodically microstructured substrate and by virtue of a doped wide-gap layer having a smooth interface to the i layer and a rough interface to the reflective contact.

In a further embodiment of the invention, the overall structure is provided with a transparent base and top contact.

In a further embodiment of the invention, the inventive photoactive components are used on curved surfaces, for example concrete, roof tiles, clay, automotive glass, etc. It is advantageous here that the inventive organic solar cells, with respect to conventional inorganic solar cells, can be applied to flexible carriers such as films, textiles, etc.

In a further embodiment of the invention, the inventive photoactive components are applied to a film or textile having an adhesive composition, for example an adhesive. It is thus possible to produce a solar adhesive film which can be arranged as required on any desired surfaces. For instance, it is possible to produce a self-adhesive solar cell.

In a further embodiment, the inventive photoactive components include a different adhesive composition in the form of a hook-and-loop connection.

In a further embodiment, the inventive photoactive components are used in conjunction with energy buffers or energy storage media, for example accumulators, capacitors etc., for connection to loads or devices.

In a further embodiment, the inventive photoactive components are used in combination with thin-film batteries.

The invention is subsequently to be illustrated in more detail with reference to some working examples.

FIG. 1 shows an individual cell with an electrode 5 adjacent to a substrate 6, a transport layer 4, a photoactive layer system 3, a transport layer 2 and a counterelectrode 1.

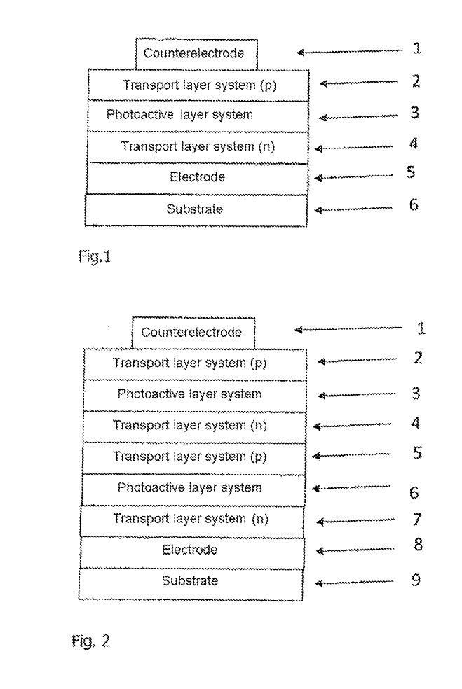

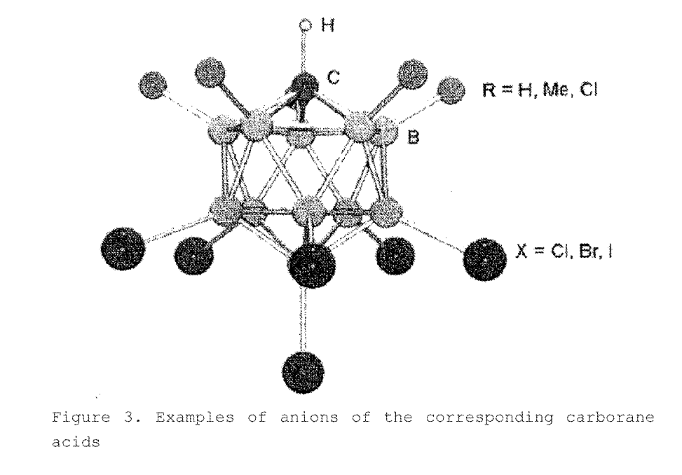

FIG. 2 shows a tandem cell with an electrode 5 adjacent to a substrate 6, two instances of a sequence of a transport layer 4 and 7, a photoactive layer system 3 and 6, a transport layer 2 and 5, and a counterelectrode 1.

FIG. 3 shows examples of anions of carborane acids claimed in accordance with the invention.

The working examples adduced detail some inventive components by way of example. The working examples are intended to describe the invention without restricting it thereto.

In one use example, by way of example, some inventive components are formed as a solar cell as follows:

### WORKING EXAMPLE 1

Substrate (1), base contact (2), n-doped transport layer (3), absorber system (4), top contact (6)

### WORKING EXAMPLE 2

Substrate (1), base contact (2), absorber system (4), p-doped transport layer (5), top contact (6)

The transport layers are typically of thickness 10-100 nm. The n-dopant and/or p-dopant used is one of the inventive compounds.

### LIST OF REFERENCE NUMERALS

1 Substrate
2 Electrode
3 Transport layer system (ETL or HTL), n-doped or p-doped
4 Photoactive layer system
5 Transport layer system (ETL or HTL), n-doped or p-doped
6 Counterelectrode
11 Substrate
12 Electrode
13 HTL or ETL layer system, n-doped or p-doped
14 Mixed layer 1
15 Mixed layer 2
16 HTL or ETL layer system, n-doped or p-doped
17 Electrode
18 Pathway of incident light

1. An organic electronic or optoelectronic component comprising:
an electrode;
a counterelectrode; and
a layer system between the electrode and the counterelectrode, the layer system comprising at least one organic layer and at least one doped layer,
wherein the dopant in the doped layer by the measure of fluoride ion affinity is a stronger Lewis acid than antimony pentafluoride (SbF₅) or is a stronger Lewis base than 1,8-bis(dimethylamino)naphthalene.

2. The component according to claim 1, wherein the dopant is an organic, organometallic or inorganic compound.

3. The component according to claim 1 or 2, wherein the dopant has at least 10, preferably 20, more preferably more than 30 and at most 100 atoms.

4. The component according to claim 3, wherein the dopant is tris(perfluoro-tert-butoxy)aluminum(III).

5. The component according to claim 3, wherein the dopant is a carborane acid of the general formula H(CB₁₁H₁₂₋ₙXₙ), especially H(CB₁₁H₆X₆) or H(CHB₁₁X₁₁), and
wherein X is selected from the group consisting of Cl, Br, I, F, CF₃ and combinations thereof, and n is an integer from 0 to 12.

6. The component according to claim 3, wherein the dopant is a [R][carborane] or [R₃₋ₐHₐSi][carborane] compound, especially [R₃C][carborane] or [R₃Si][carborane] compound, and
wherein a is an integer from 0 to 2 and R is an alkyl, aryl or heteroaryl group, [carborane] is [CB₁₁R′₁₂₋ₙXₙ]⁻, especially [CHB₁₁R′₅X₆]⁻, R′ is H, CH₃, and X is halogen, and n is an integer from 0 to 12.

7. The component according to claim 3, wherein the dopant is a metal compound from the class of the pentafluorophenylamides having the formula 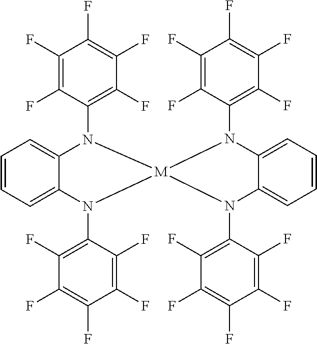
wherein M is a metal, preferably selected from a group consisting of Co, Ni, Pd and Cu.

8. The component according to claim 3, wherein the dopant is a compound of the formula [R₃Si—X—SiR₃]⁺[BAr₄]⁻, and
wherein R is independently selected from C₁-C₁₀-alkyl, C₃-C₁₀-aryl or heteroaryl or two adjacent R radicals together form a saturated or unsaturated ring, X is a halogen and Ar is a halogenated, preferably fluorinated, aryl or heteroaryl.

9. The component according to claim 3, wherein the dopant is a compound of the formula ((R₂N)₂—C═N)ₙ—Ar,
wherein R is independently C₁-C₅-alkyl, in each case substituted or unsubstituted, and
wherein two adjacent R may be joined to one another, and Ar is an aryl or heteroaryl, but preferably phenyl, naphthyl or anthryl, and n is an integer, preferably 2, 3 or 4.

10. The component according to claim 3, wherein the dopant is a compound of the formula ((RmX)—NC)nY or ((RmX)—NC)nY⁻M+, and
wherein R is in each case substituted or unsubstituted C1 to C10-alkyl, halogenated C1 to C10-alkyl, halogenyl, C3 to C14-aryl or heteroaryl having 3 to 14 aromatic atoms, X is selected from C, B, Si; Y is selected from C, B, Al; M is any cation, and n and m are each an integer, such that the molecule is outwardly uncharged.

11. The component according to claim 1, wherein the dopant occurs in the layer with a proportion by mass of at most 35%, but preferably at most 30%.

12. The component according to claim 1, wherein the component is an OLED, an organic solar cell, a field transistor (OFET) or a photodetector.

13. A method comprising:
using compounds which by the measure of fluoride ion affinity (FIA) are a stronger Lewis acid than antimony pentafluoride (SbF₅) or are a stronger Lewis base than 1,8-bis(dimethylamino)naphthalene for doping of charge carrier transport layers or active layers, and as individual layers in organic electronic or optoelectronic components.
